(19) United States
(12) Patent Application Publication
(10) Pub. No.: US 2025/0372129 A1
(43) Pub. Date: Dec. 4, 2025

(54) MEMORY DEVICE AND OPERATING METHOD OF THE MEMORY DEVICE

(71) Applicant: SK hynix Inc., Icheon-si Gyeonggi-do (KR)

(72) Inventor: Hee Youl LEE, Icheon-si Gyeonggi-do (KR)

(73) Assignee: SK hynix Inc., Icheon-si Gyeonggi-do (KR)

(21) Appl. No.: 18/988,289

(22) Filed: Dec. 19, 2024

(30) Foreign Application Priority Data
May 28, 2024 (KR) 10-2024-0069408

(51) Int. Cl. G11C 5/06; G11C 16/26

(52) U.S. Cl. CPC G11C 5/063; G11C 16/26

(57) ABSTRACT

A memory device and a method of operating the memory device are provided. The memory device includes memory cells located between a bit line and a source line, pass cells located between the memory cells, word lines coupled to the memory cells, pass word lines coupled to the pass cells, and a voltage generator configured to apply a read voltage to a selected word line among the word lines, a pass voltage to unselected word lines among the word lines, and a compensation voltage to the pass word lines during a read operation, wherein the voltage generator is configured to raise the compensation voltage more rapidly than the pass voltage.

### CROSS-REFERENCE TO RELATED APPLICATION

The present application claims priority under 35 U.S.C. § 119(a) to Korean patent application number 10-2024-0069408 filed on May 28, 2024, in the Korean Intellectual Property Office, the entire contents of which application is incorporated herein by reference.

### BACKGROUND

### 1. Technical Field

Various embodiments of the present disclosure generally relate to a memory device and an operating method of the memory device, and more particularly, to a three-dimensional memory device and a method of operating the three-dimensional memory device.

### 2. Related Art

A memory device may include a memory cell array in which data is stored and a peripheral circuit configured to perform a program operation, a read operation, or an erase operation. The memory cell array may include a plurality of memory blocks and each of the memory blocks may include may include a plurality of memory cells. The peripheral circuit may include a control circuit configured to control the operation of the memory device in response to a command transferred from a controller and circuits configured to perform a program operation, a read operation, or an erase operation under the control of the control circuit.

The memory block may include a cell plug located between a bit line and a source line. The cell plug may include a plurality of memory cells. During a read operation of the memory block, a read voltage may be applied to a selected word line coupled to a selected memory cell among the memory cells included in the cell plug, and a pass voltage may be applied to unselected word lines coupled to unselected memory cells. The read voltage may be a voltage for sensing data of the selected memory cell and the pass voltage may be a voltage for turning on the unselected memory cells to form a channel.

During a read operation, a channel of the cell plug should be formed uniformly. However, when a channel voltage that forms the channel decreases in a predetermined region, differences in the channel voltage may occur based on the region of the cell plug. A hot carrier may occur in the cell plug and threshold voltages of the memory cells may be changed due to the hot carrier.

### SUMMARY

According to an embodiment, a memory device may include memory cells located between a bit line and a source line, pass cells located between the memory cells, word lines coupled to the memory cells, pass word lines coupled to the pass cells, and a voltage generator configured to apply a read voltage to a selected word line among the word lines, a pass voltage to unselected word lines among the word lines, and a compensation voltage to the pass word lines during a read operation, wherein the voltage generator is configured to raise the compensation voltage more rapidly than the pass voltage.

According to an embodiment, a method of operating a memory device may include applying a compensation voltage to pass word lines located between word lines, applying a pass voltage to unselected word lines among the word lines, and applying a read voltage to a selected word line among the word lines when the compensation voltage rises to a first target level and the pass voltage rises to a second target level, wherein the compensation voltage rises to the first target level before the pass voltage rises to the second target level.

According to an embodiment, a method of operating a memory device may include turning on, between memory cells included in a memory block and pass cells located between the memory cells, the pass cells, turning on unselected memory cells among the memory cells after the pass cells are turned on, and reading selected memory cells among the memory cells.

### BRIEF DESCRIPTION OF THE DRAWINGS

FIG. 1 is a diagram illustrating a memory device;

FIG. 2 is a diagram illustrating the arrangement of a memory cell array and a peripheral circuit;

FIG. 3 is a perspective view illustrating a memory block;

FIG. 4 is a cross-sectional view illustrating a memory block;

FIG. 5 is a circuit diagram illustrating a memory block;

FIGS. 6, 7A, and 7B are diagrams illustrating a read operation according to first embodiments of the present disclosure;

FIGS. 8 and 9 are diagrams illustrating a read operation according to second embodiments of the present disclosure;

FIGS. 10 and 11 are diagrams illustrating a read operation according to third embodiments of the present disclosure;

FIG. 12 is a diagram illustrating the effect of an embodiment of the present disclosure;

FIG. 13 is a diagram illustrating a memory card system to which a memory device according to an embodiment of the present disclosure is applied; and

FIG. 14 is a diagram illustrating a solid state drive (SSD) system to which a memory device according to an embodiment of the present disclosure is applied.

### DETAILED DESCRIPTION

Specific structural or functional descriptions disclosed below are exemplified to describe various embodiments according to the concepts of the present disclosure. The embodiments according to the concepts of the present disclosure are not construed as being limited to the embodiments described below, and may be variously modified and replaced with other equivalent embodiments.

Hereinafter, terms such as first and second may be used to describe various components, but the components are not limited by the terms. These terms are used for the purpose of distinguishing one component from another component and are not intended to imply an order or number of elements. Thus, a first element in some embodiments could be termed a second element in other embodiments without departing from the teachings of the present disclosure.

Various embodiments are directed to a memory device and a method of operating the memory device capable of improving reliability of the read operation of the memory device.

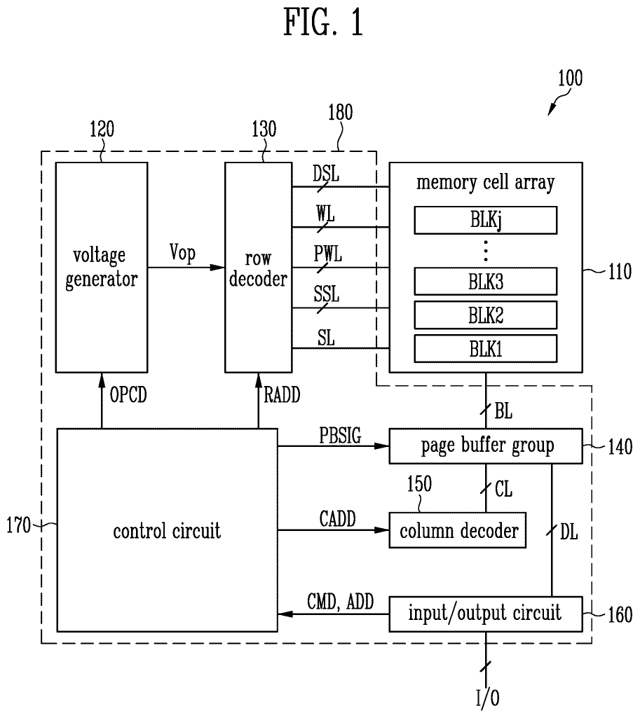

FIG. 1 is a diagram illustrating a memory device 100.

Referring to FIG. 1, the memory device 100 may include a memory cell array 110 in which data is stored and a peripheral circuit 180 configured to perform a program operation, a read operation, or an erase operation.

The memory cell array 110 may include first to jth memory blocks BLK1 to BLKj in which data is stored. Each of the first to jth memory blocks BLK1 to BLKj may include a plurality of memory cells, and the memory cells may have a two-dimensional structure arranged in parallel to a substrate or a three-dimensional structure stacked in a vertical direction on the substrate. The first to jth memory blocks BLK1 to BLKj according to embodiments of the present disclosure may have the three-dimensional structure. Drain select lines DSL, word lines WL, pass word lines PWL, source select lines SSL, and a source line SL may be coupled to each of the first to jth memory blocks BLK1 to BLKj.

The peripheral circuit 180 may include a voltage generator 120, a row decoder 130, a page buffer group 140, a column decoder 150, an input/output circuit 160, and a control circuit 170.

The voltage generator 120 may generate and output operating voltages Vop for various operations in response to an operation code OPCD. For example, the voltage generator 120 may generate and output program voltages, verify voltages, read voltages, pass voltages, compensation voltages, pre-compensation voltages, erase voltages, and turn-on voltages.

A program voltage may be a voltage for increasing a threshold voltage of a selected memory cell during a program operation. A verify voltage may be a voltage for verifying the threshold voltage of the selected memory cell. A read voltage may be a voltage for reading data of the selected memory cell during a read operation. A pass voltage may be a voltage for turning on unselected memory cells. A compensation voltage may be a voltage for turning on a pass cell. A pre-compensation voltage may be used before, after, or both before and after applying the compensation voltage to the pass word lines PWL to turn on the memory cells with the compensation voltage. An erase voltage may be a voltage for erasing the memory cell. A turn-on voltage may be a voltage for turning on a drain select transistor or a source select transistor.

The voltage generator 120 may control the level, output time, or blocking time of each of the operating voltages Vop in response to the operation code OPCD.

The row decoder 130 may select one memory block among the first to jth memory blocks BLK1 to BLKj included in the memory cell array 110 and may transfer the operating voltages Vop to the selected memory block according to a row address RADD.

The page buffer group 140 may be coupled to the memory cell array 110 through bit lines BL. For example, the page buffer group 140 may include page buffers (not shown) coupled to the bit lines BL, respectively. The page buffers may operate simultaneously in response to page buffer control signals PBSIG and may store data during the program operation or the read operation. Each of the page buffers may include a plurality of latches to store data. The number of latches may vary according to a program method. For example, the page buffers may be designed differently based on the number of bits that are stored in a single memory cell and may also be explained differently depending on the number of verify voltages used during a verify operation. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

The column decoder 150 may transfer data between the input/output circuit 160 and the page buffer group 140 according to a column address CADD.

The input/output circuit 160 may be coupled to a controller 1200 through input/output lines I/O. The input/output circuit 160 may input or output a command CMD, an address ADD, and the data through the input/output lines I/O. For example, the input/output circuit 160 may transfer the command CMD and the address ADD, which are received from the input/output lines I/O, to the control circuit 170 and may transfer the data, which are received from the input/output lines I/O, to the column decoder 150. The input/output circuit 160 may output the data, which are received from the column decoder 150, to an external device through the input/output lines I/O.

The control circuit 170 may be configured to output the operation code OPCD, the row address RADD, the page buffer control signals PBSIG, and the column address CADD in response to the command CMD and the address ADD. For example, the control circuit 170 may be composed of software for performing the program operation, the read operation, or the erase operation in response to the command CMD and the address ADD and hardware for outputting the operation code OPCD, the row address RADD, the page buffer control signals PBSIG, and the column address CADD according to the control of the software.

The control circuit 170 may control the operation code OPCD in order for the compensation voltage applied to the pass word lines PWL to have a controlled rising slope during a read operation of the selected memory block. For example, the control circuit 170 may control the operation code OPCD so that a rising slope of the compensation voltage may be higher than that of the pass voltage applied to the unselected word lines among the word lines WL. For example, the control circuit 170 may control the operation code OPCD so that the compensation voltage may reach a target level faster than the pass voltage. The target level of the compensation voltage may be the same as that of the pass voltage. The control circuit 170 may control the operation code OPCD so that the pre-compensation voltage may be applied to the pass word lines PWL before the compensation voltage is applied to the pass word lines PWL. The control circuit 170 may control the operation code OPCD so that the pre-compensation voltage may be applied to the pass word lines PWL after the compensation voltage is applied to the pass word lines PWL.

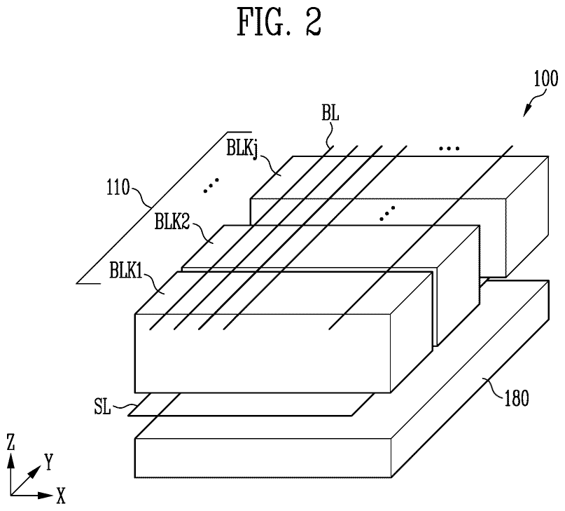

FIG. 2 is a diagram for explaining the arrangement of the memory cell array 100 and the peripheral circuit 180.

Referring to FIG. 2, the memory device 100 may include the peripheral circuit 180 and the memory cell array 110. The peripheral circuit 180 may be disposed over a base (not shown) and the memory cell array 110 may be disposed over the peripheral circuit 180. The base may be a substrate. The memory cell array 110 may include the first to jth memory blocks BLK1 to BLKj. The bit lines BL may be disposed over the first to jth memory blocks BLK1 to BLKj and the source line SL may be disposed under the first to jth memory blocks BLK1 to BLKj. Though not shown, the bit lines BL may be disposed under the first to jth memory blocks BLK1 to BLKj and the source line SL may be disposed over the first to jth memory blocks BLK1 to BLKj.

The bit lines BL may be spaced apart each other in an X direction and may be extended in a Y direction. The source line SL may be commonly coupled to the first to jth memory blocks BLK1 to BLKj. The first to jth memory blocks BLK1 to BLKj may be configured identically to each other.

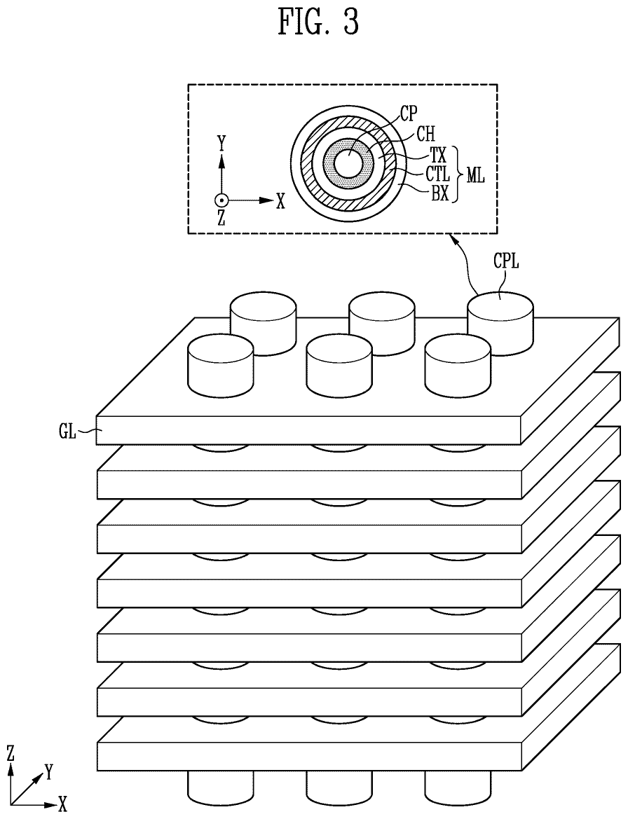

FIG. 3 is a perspective view illustrating a memory block.

Referring to FIG. 3, a portion of the memory block is shown. The memory block may include gate lines GL that are stacked apart from each other. For example, the gate lines GL may be stacked apart from each other in a Z direction. The gate lines GL may include a source select line, a word line, a pass word line, and a drain select line. The gate lines GL may include a conductive material. For example, the gate lines GL may include a metal material such as tungsten (W), molybdenum (Mo), cobalt (Co), nickel (Ni), or a semiconductor material such as silicon (Si) or polysilicon (Poly-Si). However, the materials of the gate lines GL are not necessarily limited thereto.

Cell plugs CPL may penetrate the gate lines GL. For example, the cell plugs CPL may penetrate the gate lines GL in the Z direction. The cell plugs CPL may include a core pillar CP, a channel layer CH, and a memory layer ML. The memory layer ML may include a tunnel isolation layer TX, a charge trap layer CTL, and a blocking layer BX. The core pillar CP may have a cylindrical shape, a rectangular pillar shape, or a polygonal pillar shape and may include an insulating material or a conductive material. The channel layer CH may surround a side surface of the core pillar CP and may include polysilicon. The tunnel isolation layer TX may surround a side surface of the channel layer CH and may include an oxide layer. The charge trap layer CTL may surround a side surface of the tunnel isolation layer TX and may include a nitride layer. The blocking layer BX may surround a side surface of the charge trap layer CTL and may include an oxide layer. The cell plugs CPL may include a source select transistor, a drain select transistor, a memory cell, and a pass cell.

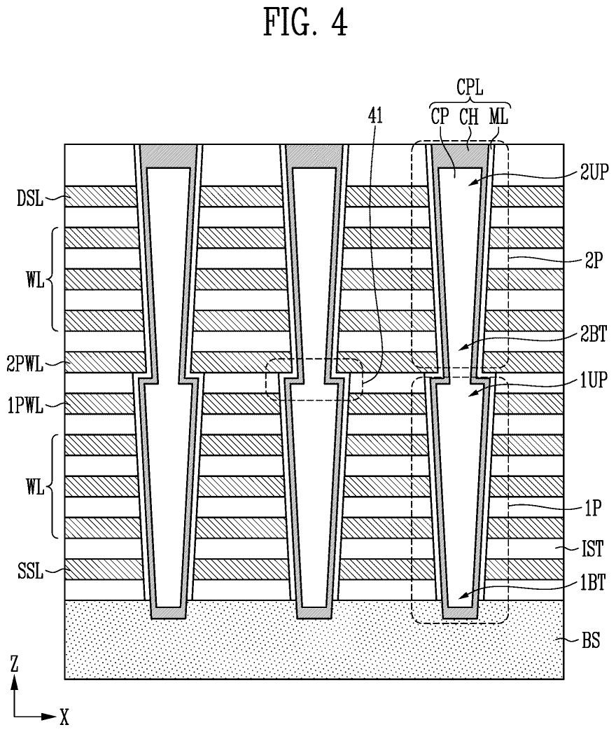

FIG. 4 is a cross-sectional view illustrating a memory block.

FIG. 4 is a cross-sectional view taken along the memory block shown in FIG. 3 in an XZ plane.

Referring to FIGS. 3 and 4, the gate lines GL may include the source select line SSL, the word lines WL, first and second pass word lines 1PWL and 2PWL, and the drain select line DSL. The number of lines shown in FIGS. 3 and 4 may vary depending on the memory device. Insulating layers IST may be located between the gate lines GL. The insulating layers IST may be oxide layers. For example, the insulating layers IST may be silicon oxide layers. The gate lines GL and the insulating layers IST may be stacked over a base BS. In an embodiment, the base BS may be a substrate.

The cell plugs CPL may penetrate the source select line SSL, the word lines WL, the first and second pass word lines 1PWL and 2PWL, and the drain select line DSL, and the insulating layers IST. The cell plugs CPL may include stacked first and second plugs 1P and 2P. The second plug 2P may be extended over the first plug 1P. Among various processes that are performed to form the cell plug CPL, widths of upper portions 1UP and 2UP of the first and second plugs 1P and 2P may be greater than widths of lower portions 1BT and 2BT, respectively, due to the characteristics of the etching process. For example, the width of the upper portion 1UP of the first plug 1P may be greater than the width of the lower portion 1BT of the first plug 1P, and the width of the upper portion 2UP of the second plug 2P may be greater than the width of the lower portion 2BT of the second plug 2P. The width of the upper portion 1UP of the first plug 1P may be greater than the width of the lower portion 2BT of the second plug 2P. Accordingly, a drastic difference in width may occur in a portion 41 where the first plug 1P and the second plug 2P are in contact. A portion of the gate lines GL adjacent to the portion 41 may serve as the pass word line PWL, not the word line WL. The pass word line PWL may be a dummy line. For example, the gate line GL that is located at the uppermost portion of the first plug 1P may be designated as the first pass word line 1PWL and the gate line GL that is located at the lowermost portion of the second plug 2P may be designated as a second pass word line 2PWL. During the read operation, the compensation voltage or the pre-compensation voltage, not the read voltage or the pass voltage, may be applied to the first and second pass word lines 1PWL and 2PWL.

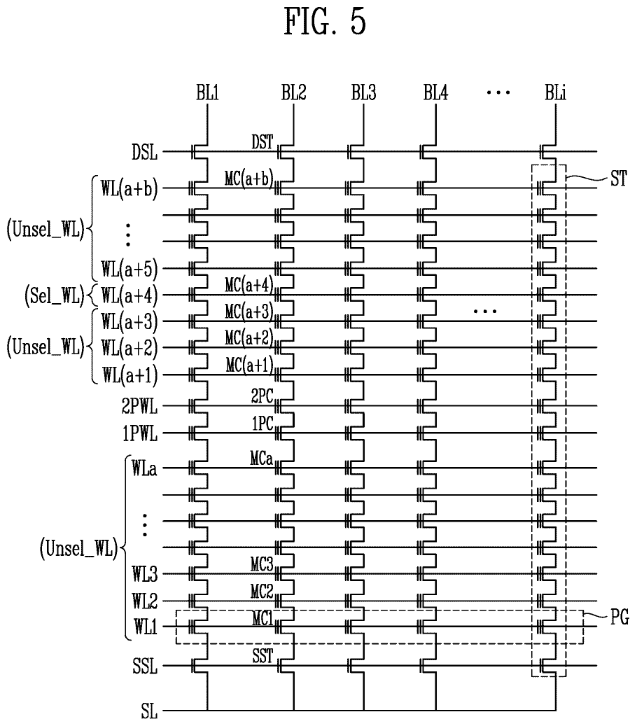

FIG. 5 is a circuit diagram illustrating a memory block.

FIG. 5 shows one memory block among the first to jth memory blocks BLK1 to BLKj shown in FIG. 1.

Referring to FIGS. 4 and 5, the memory block may include the source line SL and cell strings ST that are coupled between first to ith bit lines BL1 to BLi. For example, the cell plug CPL shown in FIG. 4 may include the cell string ST. The first to ith bit lines BL1 to BLi may be respectively coupled to the cell strings ST and the source line SL may be commonly coupled to the cell strings ST.

The cell strings ST may include the source select transistors SST, first to ath memory cells MC1 to MCa, first pass cells 1PC, second pass cells 2PC, (a+1)th to (a+b)th memory cells MC(a+1) to MC(a+b), and drain select transistors DST. As FIG. 5 shows an example of a configuration of the cell strings ST, the number of source select transistors SST, the number of first to ath memory cells MC1 to MCa, the number of first pass cells 1PC, the number of second pass cells 2PC, the number of (a+1)th to (a+b)th memory cells MC(a+1) to MC(a+b), and the number of drain select transistors DST are not limited thereto.

Gates of the source select transistor SST included in different cell strings ST may be coupled to the source select line SSL. Gates of the first to ath memory cells MC1 to MCa and gates of the (a+1)th to (a+b)th memory cells MC(a+1) to MC(a+b) may be coupled to first to ath word lines WL1 to WLa and (a+1)th to (a+b)th word lines MC(a+1) to MC(a+b), respectively. Gates of the first pass cells 1PC may be coupled to the first pass word line 1PWL and gates of the second pass cells 2PC may be coupled to the second pass word line 2PWL. Gates of the drain select transistors DST may be coupled to the drain select line DSL.

A group of memory cells that are coupled to the same word line may be a page PG. A program operation or a read operation may be performed in units of the page PG.

During the read operation, assuming that an (a+4)th word line WL(a+4) is a selected word line Sel_WL, the remaining first to ath word lines WL1 to WLa, (a+1)th to (a+3)th word lines WL(a+1) to WL(a+3), and (a+5)th to (a+b)th word lines WL(a+5) to WL(a+B) may be unselected word lines Unsel_WL. Memory cells that are coupled to the selected word line Sel_WL may be selected memory cells, and memory cells that are coupled to the unselected word lines Unsel_WL may be unselected memory cells. During the read operation, data of the selected memory cells may be read. When the read operation of the selected memory cells is performed, the unselected memory cells and the first and second pass cells 1PC and 2PC may be turned on to form a channel in the cell strings ST. The unselected memory cells may be turned on or off by voltages that are applied to the unselected word lines Unsel_WL. The first and second pass cells 1PC and 2PC may be turned on or off by voltages that are applied to the first and second pass word lines 1PWL and 2PWL.

As described above with reference to FIG. 4, the first and second word lines 1PWL and 2PWL may be located at the portion 41 where the electrical characteristics, in an embodiment, may be relatively degraded compared to other regions. Accordingly, in an embodiment, when the same voltages are applied to the unselected word lines Unsel_WL and the first and second pass word lines 1PWL and 2PWL at the same time, the first and second pass cells 1PC and 2PC may be turned on slower than the unselected memory cells or may be turned on at a lower turn-on level than a turn-on level of the unselected memory cells.

When the first and second pass cells 1PC and 2PC are turned on slower than the unselected memory cells or turned on at the lower turn-on level than the turn-on level of the unselected memory cells, a voltage difference may occur between a channel voltage of the first plug 1P and a channel voltage of the second plug 2P. When the voltage difference occurs in the channel, hot carriers may be generated due to the voltage difference. When the hot carriers are injected into the memory cell, the threshold voltage of the memory cell may change, thereby decreasing the reliability of the read operation.

In various embodiments that are described below, voltages applied to the unselected word lines Unsel_WL may be controlled differently from voltages applied to the first and second pass word lines 1PWL and 2PWL to improve the reliability of a read operation.

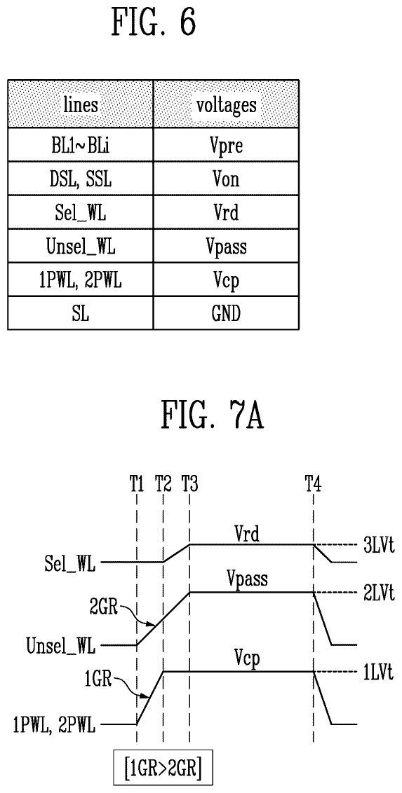

FIGS. 6, 7A, and 7B are diagrams illustrating a read operation according to first embodiments of the present disclosure.

Referring to FIG. 6, during the read operation, lines coupled to the selected memory block and voltages applied to the lines are shown. During the read operation according to the first embodiment, a pre-charge voltage Vpre may be applied to the first to ith bit lines BL1 to BLi. As used herein, the tilde “˜” indicates a range of components. For example, “BL1˜BLi” indicates the inverters BL1, BL2, . . . , and BLi shown in FIG. 6. The pre-charge voltage Vpre may be a positive voltage that is greater than 0 V and may be output from the page buffer group 140 of FIG. 1. A turn-on voltage Von may be applied to the drain select line DSL and the source select line SSL. The turn-on voltage Von may be a positive voltage that is greater than 0 V and may be set to a level at which drain select transistors and source select transistors are turned on. A read voltage Vrd may be applied to the selected word line Sel_WL. The read voltage Vrd may be set differently according to threshold voltages of programmed memory cells. A pass voltage Vpass may be applied to the unselected word lines Unsel_WL. The pass voltage Vpass may be a positive voltage that is greater than 0 V and may be set to a level at which the unselected memory cells are turned on.

A compensation voltage Vcp may be applied to the first and second pass word lines 1PWL and 2PWL. The compensation voltage Vcp may be a positive voltage that is greater than 0 V and may be set to be greater than or equal to the target level of the pass voltage Vpass. The compensation voltage Vcp may be configured to rise to the target level more rapidly than the pass voltage Vpass. A ground voltage GND may be applied to the source line SL.

Among the aforementioned voltages, methods by which the read voltage Vrd, the pass voltage Vpass, and the compensation voltage Vcp are applied to the lines will be described below as follows.

Referring to FIG. 7A, the pass voltage Vpass may be applied to the unselected word lines Unsel_WL and the compensation voltage Vcp may be applied to the first and second pass word lines 1PWL and 2PWL at a first time T1 during the read operation. The compensation voltage Vcp may rise to a first target level 1LVt and the pass voltage Vpass may rise to a second target level 2LVt. The first target level 1LVt may be set to be greater than or equal to the target level of the second target level 2LVt.

The compensation voltage Vcp and the pass voltage Vpass may be generated and output by the voltage generator 120 of FIG. 1. The voltage generator 120 may raise a level of the compensation voltage Vcp more rapidly than the level of the pass voltage Vpass. For example, the control circuit 170 of FIG. 1 may output the operation code OPCD so that the compensation voltage Vcp may rise more rapidly than the pass voltage Vpass. The voltage generator 120 may generate and output the compensation voltage Vcp which rises more rapidly than the pass voltage Vpass. For example, assuming that a rising slope of the compensation voltage Vcp is a first slope 1GR and a rising slope of the pass voltage Vpass is a second slope 2GR, the first slope 1GR may be greater than the second slope 2GR. A rising slope refers to a level of change in voltage that has increased during the same time.

Accordingly, at a second time T2, the compensation voltage Vcp applied to the first and second pass word lines 1PWL and 2PWL may rise to the first target level 1LVt and the pass voltage Vpass may have a level that is lower than the level of the compensation voltage Vcp. At the second time T2, the read voltage Vrd may be applied to the selected word line Sel_WL. However, the time at which the read voltage Vrd is applied is not limited to the second time T2.

Between the second time T2 and a third time T3, as the compensation voltage Vcp is maintained at the first target level 1LVt and the pass voltage Vpass has the level that is lower than the level of the compensation voltage Vcp, the first and second pass cells 1PC and 2PC coupled to the first and second pass word lines 1PWL and 2PWL may be turned on earlier than the unselected memory cells. The unselected memory cells may be turned off according to the level of the pass voltage Vpass or may be turned on at a level that is lower than levels of the first and second pass cells 1PC and 2PC.

At the third time T3, the pass voltage Vpass may rise to the second target level 2LVt and the read voltage Vrd may rise to a third target level 3LVt. However, the time at which the read voltage Vrd reaches the third target level 3LVt is not limited to the third time T3.

Between the third time T3 and a fourth time T4, as the compensation voltage Vcp is maintained at the first target level 1LVt, the pass voltage Vpass is maintained at the second target level 2LVt, and the read voltage Vrd is maintained at the third target level 3LVt, a channel may be formed in cell strings. Memory cells may be read according to the read voltage Vrd. At the fourth time T4, the selected word line Sel_WL, the unselected word lines Unsel_WL, and the first and second pass word lines 1PWL and 2PWL may be discharged.

Referring to FIG. 7B, when read operations using different read voltages are continuously performed, the compensation voltage Vcp applied to the first and second pass word lines 1PWL and 2PWL may be maintained at the first target level 1LVt even when the read voltage is changed. The read operations will be described below as follows.

During the read operation, the pass voltage Vpass may be applied to the unselected word lines Unsel_WL and the compensation voltage Vcp may be applied to the first and second pass word lines 1PWL and 2PWL at the first time T1. The compensation voltage Vcp may rise to the first target level 1LVt and the pass voltage Vpass may rise to the second target level 2LVt. The first target level 1LVt may be set to be greater than or equal to the target level of the second target level 2LVt.

The compensation voltage Vcp and the pass voltage Vpass may be generated and output by the voltage generator 120 of FIG. 1. The voltage generator 120 may raise the level of the compensation voltage Vcp more rapidly than the level of the pass voltage Vpass. For example, the control circuit 170 of FIG. 1 may output the operation code OPCD so that the compensation voltage Vcp may rise more rapidly than the pass voltage Vpass. The voltage generator 120 may generate and output the compensation voltage Vcp which rises more rapidly than the pass voltage Vpass. For example, assuming that a rising slope of the compensation voltage Vcp is the first slope 1GR and the rising slope of the pass voltage Vpass is the second slope 2GR, the first slope 1GR may be greater than the second slope 2GR. A rising slope refers to a level of change in voltage that has increased during the same time.

Accordingly, at the second time T2, the compensation voltage Vcp applied to the first and second pass word lines 1PWL and 2PWL may rise to the first target level 1LVt, and the pass voltage Vpass may have the level that is lower than the level of the compensation voltage Vcp. At the second time T2, a first read voltage 1Vrd may be applied to the selected word line Sel_WL. However, the time at which the first read voltage 1Vrd is applied is not limited to the second time T2.

Between the second time T2 and the third time T3, as the compensation voltage Vcp is maintained at the first target level 1LVt and the pass voltage Vpass has the level that is lower than the level of the compensation voltage Vcp, the first and second pass cells 1PC and 2PC coupled to the first and second pass word lines 1PWL and 2PWL may be turned on earlier than the unselected memory cells. The unselected memory cells may be turned off according to the level of the pass voltage Vpass or may be turned on at the level that is lower than levels of the first and second pass cells 1PC and 2PC.

At the third time T3, the pass voltage Vpass may rise to the second target level 2LVt and the first read voltage 1Vrd may rise to the third target level 3LVt. However, the time at which the first read voltage 1Vrd reaches the third target level 3LVt is not limited to the third time T3.

Between the third time T3 and the fourth time T4, as the compensation voltage Vcp is maintained at the first target level 1LVt, the pass voltage Vpass is maintained at the second target level 2LVt, and the first read voltage 1Vrd is maintained at the third target level 3LVt, a channel may be formed in cell strings. Memory cells may be read according to the first read voltage 1Vrd. At the fourth time T4, the selected word line Sel_WL and the unselected word lines Unsel_WL may be discharged. The first and second pass word lines 1PWL and 2PWL might not be discharged. The compensation voltage Vcp applied to the first and second pass word lines 1PWL and 2PWL may be maintained.

At a fifth time T5, the pass voltage Vpass may be applied again to the unselected word lines Unsel_WL. The compensation voltage Vcp applied to the first and second pass word lines 1PWL and 2PWL may be maintained. The pass voltage Vpass may rise between the fifth time T5 and a seventh time T7.

At a sixth time T6, which is prior to the seventh time T7, a second read voltage 2Vrd may be applied to the selected word line Sel_WL. In FIG. 7B, the second read voltage 2Vrd is described as being higher than the first read voltage 1Vrd. However, the second read voltage 2Vrd may be set to be lower than the first read voltage 1Vrd depending on the sequence of the read operation. In addition, the time at which the second read voltage 2Vrd is applied to the selected word line Sel_WL is not limited to the sixth time T6. In an embodiment, the second read voltage 2Vrd may be referred to as a next read voltage and the first read voltage 1Vrd may be referred to as a read voltage.

Assuming that the time difference between the first and third times T1 and T3 in which the pass voltage Vpass is applied to the unselected word lines Unsel_WL is referred to as a first time difference 1Dt, a second time difference 2Dt between the fifth and seventh times T5 and T7 may be less than or equal to the first time difference 1Dt (that is, 1Dt≥2Dt).

In other words, from the first to third times T1 to T3, the first time difference 1Dt should be maintained so that the compensation voltage Vcp may reach the target level more rapidly than the pass voltage Vpass. However, from the fifth to seventh times T5 to T7, as the compensation voltage Vcp is already maintained at the first target level 1LVt, the pass voltage Vpass applied to the unselected word lines Unsel_WL may rise more rapidly to the second target level 2LVt. The second read voltage 2Vrd may rise to a fourth target level 4LVt more rapidly than a time at which the first read voltage 1Vrd rises to the third target level 3LVt.

Accordingly, between the fifth and seventh times T5 and T7, a third slope 3GR of the pass voltage Vpass may be greater than or equal to the second slope 2GR (that is, 3GR≥2GR).

Between the seventh time T7 and an eighth time T8, as the compensation voltage Vcp is maintained at the first target level 1LVt, the pass voltage Vpass is maintained at the second target level 2LVt, and the second read voltage 2Vrd is maintained at the fourth target level 4LVt, a channel may be formed in cell strings. Memory cells may be read according to the second read voltage 2Vrd. At the eighth time T8, the selected word line Sel_WL, the unselected word lines Unsel_WL, and the first and second pass word lines 1PWL and 2PWL may be discharged.

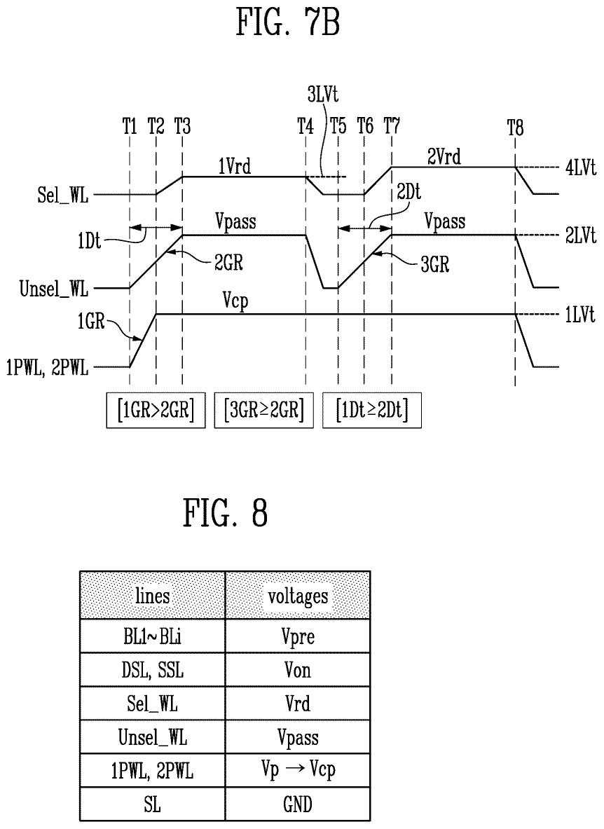

FIGS. 8 and 9 are diagrams illustrating a read operation according to a second embodiment of the present disclosure.

Referring to FIG. 8, during a read operation, lines that are coupled to the selected memory block and voltages that are applied to the lines are shown. During the read operation according to the second embodiment, the pre-charge voltage Vpre may be applied to the first to ith bit lines BL1 to BLi. The pre-charge voltage Vpre may be a positive voltage that is higher than 0 V and may be output from the page buffer group 140 of FIG. 1. The turn-on voltage Von may be applied to the drain select line DSL and the source select line SSL. The turn-on voltage Von may be a positive voltage that is higher than 0 V and may be set to a level at which drain select transistors and source select transistors are turned on. The read voltage Vrd may be applied to the selected word line Sel_WL. The read voltage Vrd may be set differently according to threshold voltages of programmed memory cells. The pass voltage Vpass may be applied to the unselected word lines Unsel_WL. The pass voltage Vpass may be a positive voltage that is higher than 0 V and may be set to a level at which the unselected memory cells are turned on.

After a pre-compensation voltage Vp is applied to the first and second pass word lines 1PWL and 2PWL, the compensation voltage Vcp may be applied to the first and second pass word lines 1PWL and 2PWL. The pre-compensation voltage Vp may be set to a level which is higher than 0 V and is lower than the level of the pass voltage Vpass. The pre-compensation voltage Vp may be used before the compensation voltage Vcp is applied to the first and second pass word lines 1PWL and 2PWL to increase the voltages of the first and second pass word lines 1PWL and 2PWL in advance. The ground voltage GND may be applied to the source line SL.

The compensation voltage Vcp may be a positive voltage that is higher than the pre-compensation voltage Vp and may be set to be greater than or equal to the level of the pass voltage Vpass. The pre-compensation voltage Vp may be configured to rise to the target level more rapidly than the pass voltage Vpass. The ground voltage GND may be applied to the source line SL.

Among the aforementioned voltages, methods by which the read voltage Vrd, the pass voltage Vpass, and the compensation voltage Vcp are applied to the lines will be described below as follows.

Referring to FIG. 9, during the read operation, the pre-compensation voltage Vp may be applied to the first and second pass word lines 1PWL and 2PWL at the first time T1. A ground voltage or 0 V may be applied to the unselected word lines Unsel_WL. The first to fifth times T1 to T5 shown in FIG. 9 are not related to the first to fourth times T1 to T4 shown in FIG. 7A or the first to eighth times T1 to T8 shown in FIG. 7B.

The pre-compensation voltage Vp may be generated and output by the voltage generator 120 of FIG. 1. When the pre-compensation voltage Vp is applied to the first and second pass word lines 1PWL and 2PWL, turn-on levels of the first and second pass cells 1PC and 2PC of FIG. 5 coupled to the first and second pass word lines 1PWL and 2PWL may rise.

At the second time T2, the pass voltage Vpass may be applied to the unselected word line Unsel_WL and the compensation voltage Vcp may be applied to the first and second pass word lines 1PWL and 2PWL. The compensation voltage Vcp may rise to the first target level 1LVt and the pass voltage Vpass may rise to the second target level 2LVt. The first target level 1LVt may be set to be greater than or equal to the target level of the second target level 2LVt.

The compensation voltage Vcp and the pass voltage Vpass may be generated and output by the voltage generator 120. The voltage generator 120 may raise the level of the compensation voltage Vcp more rapidly than the level of the pass voltage Vpass. For example, the control circuit 170 of FIG. 1 may output the operation code OPCD so that the compensation voltage Vcp may rise more rapidly than the pass voltage Vpass. The voltage generator 120 may generate and output the compensation voltage Vcp which rises more rapidly than the pass voltage Vpass. For example, assuming that a rising slope of the compensation voltage Vcp is a fourth slope 4GR and the rising slope of the pass voltage Vpass is the second slope 2GR, the fourth slope 4GR may be greater than the second slope 2GR (that is, 4GR>2GR). A rising slope refers to a level of change in voltage that has increased during the same time.

Accordingly, at the third time T3, the compensation voltage Vcp applied to the first and second pass word lines 1PWL and 2PWL may rise to the first target level 1LVt, and the pass voltage Vpass may have a level that is lower than the level of the compensation voltage Vcp. At the third time T3, the read voltage Vrd may be applied to the selected word line Sel_WL. However, the time at which the read voltage Vrd is applied is not limited to the third time T3.

Between the third time T3 and the fourth time T4, as the compensation voltage Vcp is maintained at the first target level 1LVt and the pass voltage Vpass has a level that is lower than the level of the compensation voltage Vcp, the first and second pass cells 1PC and 2PC coupled to the first and second pass word lines 1PWL and 2PWL may be turned on earlier than the unselected memory cells. The unselected memory cells may be turned off according to the level of the pass voltage Vpass or may be turned on at the level that is lower than the levels of the first and second pass cells 1PC and 2PC.

At the fourth time T4, the pass voltage Vpass may rise to the second target level 2LVt and the read voltage Vrd may rise to the third target level 3LVt. However, the time at which the read voltage Vrd reaches the third target level 3LVt is not limited to the third time T3.

Between the fourth time T4 and the fifth time T5, as the compensation voltage Vcp is maintained at the first target level 1LVt, the pass voltage Vpass is maintained at the second target level 2LVt, and the read voltage Vrd is maintained at the third target level 3LVt, a channel may be formed in cell strings. Memory cells may be read according to the read voltage Vrd. At the fifth time T5, the selected word line Sel_WL, the unselected word lines Unsel_WL, and the first and second pass word lines 1PWL and 2PWL may be discharged.

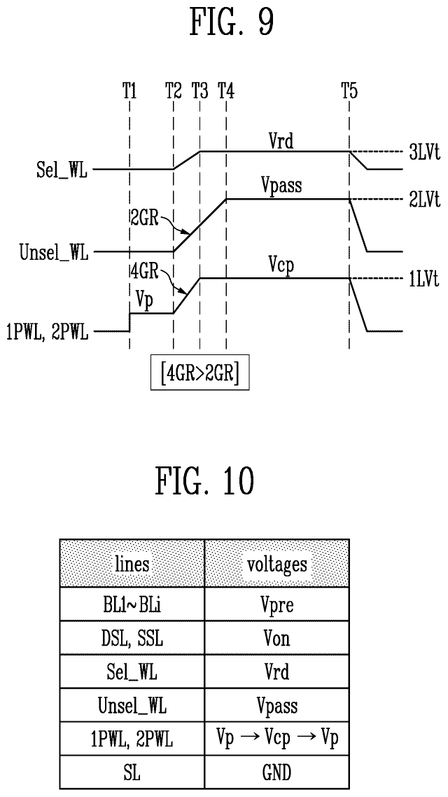

FIGS. 10 and 11 are diagrams illustrating a read operation according to third embodiments of the present disclosure.

Referring to FIG. 10, during the read operation, lines that are coupled to the selected memory block and voltages that are applied to the lines are shown. During the read operation according to the third embodiments, the pre-charge voltage Vpre may be applied to the first to ith bit lines BL1 to BLi. The pre-charge voltage Vpre may be a positive voltage that is higher than 0 V and may be output from the page buffer group 140 of FIG. 1. The turn-on voltage Von may be applied to the drain select line DSL and the source select line SSL. The turn-on voltage Von may be a positive voltage that is higher than 0 V and may be set to a level at which drain select transistors and source select transistors are turned on. The read voltage Vrd may be applied to the selected word line Sel_WL. The read voltage Vrd may be set differently according to threshold voltages of programmed memory cells. The pass voltage Vpass may be applied to the unselected word lines Unsel_WL. The pass voltage Vpass may be a positive voltage that is higher than 0 V and may be set to a level at which the unselected memory cells are turned on.

After the pre-compensation voltage Vp is applied to the first and second pass word lines 1PWL and 2PWL, the compensation voltage Vcp may be applied to the first and second pass word lines 1PWL and 2PWL, and the pre-compensation voltage Vp may further be applied. The pre-compensation voltage Vp may be set to a level which is higher than 0 V and is lower than the level of the compensation voltage Vcp. Before the compensation voltage Vcp is applied to the first and second pass word lines 1PWL and 2PWL, the pre-compensation voltage Vp may be used to increase the voltages of the first and second pass word lines 1PWL and 2PWL in advance. In addition, the pre-compensation voltage Vp may be used for a predetermined time to turn on the first and second pass cells 1PC and 2PC of FIG. 5 after the compensation voltage Vcp is applied to the first and second pass word lines 1PWL and 2PWL. The word “predetermined” as used herein with respect to a parameter, such as a predetermined time, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

The compensation voltage Vcp may be a positive voltage that is higher than the pre-compensation voltage Vp and may be set to be greater than or equal to the target level of the pass voltage Vpass. The compensation voltage Vcp may be set to rise to the target level more rapidly than the pass voltage Vpass. The ground voltage GND may be applied to the source line SL.

Among the aforementioned voltages, methods by which the read voltage Vrd, the pass voltage Vpass, and the compensation voltage Vcp are applied to the lines will be described below as follows.

Referring to FIG. 11, during a read operation, the pre-compensation voltage Vp may be applied to the first and second pass word lines 1PWL and 2PWL at the first time T1. A ground voltage or 0 V may be applied to the unselected word lines Unsel_WL.

The pre-compensation voltage Vp may be generated and output by the voltage generator 120 of FIG. 1. When the pre-compensation voltage Vp is applied to the first and second pass word lines 1PWL and 2PWL, the turn-on levels of the first and second pass cells 1PC and 2PC of FIG. 5 coupled to the first and second pass word lines 1PWL and 2PWL may rise.

At the second time T2, the pass voltage Vpass may be applied to the unselected word line Unsel_WL and the compensation voltage Vcp may be applied to the first and second pass word lines 1PWL and 2PWL. The compensation voltage Vcp may rise to the first target level 1LVt and the pass voltage Vpass may rise to the second target level 2LVt. The first target level 1LVt may be set to be greater than or equal to the target level of the second target level 2LVt.

The compensation voltage Vcp and the pass voltage Vpass may be generated and output by the voltage generator 120. The voltage generator 120 may raise the level of the compensation voltage Vcp more rapidly than the level of the pass voltage Vpass. For example, the control circuit 170 of FIG. 1 may output the operation code OPCD so that the compensation voltage Vcp may rise more rapidly than the pass voltage Vpass. The voltage generator 120 may generate and output the compensation voltage Vcp which rises more rapidly than the pass voltage Vpass. For example, assuming that a rising slope of the compensation voltage Vcp is the fourth slope 4GR and the rising slope of the pass voltage Vpass is the second slope 2GR, the fourth slope 4GR may be greater than the second slope 2GR (that is, 4GR>2GR). A rising slope refers to a level of change in voltage that has increased during the same time.

Accordingly, at the third time T3, the compensation voltage Vcp applied to the first and second pass word lines 1PWL and 2PWL may rise to the first target level 1LVt, and the pass voltage Vpass may have a level that is lower than the level of the compensation voltage Vcp. At the third time T3, the read voltage Vrd may be applied to the selected word line Sel_WL. However, the time at which the read voltage Vrd is applied is not limited to the third time T3.

Between the third time T3 and the fourth time T4, as the compensation voltage Vcp is maintained at the first target level 1LVt and the pass voltage Vpass has a level that is lower than the compensation voltage Vcp, the first and second pass cells 1PC and 2PC coupled to the first and second pass word lines 1PWL and 2PWL may be turned on earlier than the unselected memory cells. The unselected memory cells may be turned off according to the level of the pass voltage Vpass or may be turned on at a level that is lower than the first and second pass cells 1PC and 2PC.

At the fourth time T4, the pass voltage Vpass may rise to the second target level 2LVt and the read voltage Vrd may rise to the third target level 3LVt. However, the time at which the read voltage Vrd reaches the third target level 3LVt is not limited to the third time T3.

Between the fourth time T4 and the fifth time T5, as the compensation voltage Vcp is maintained at the first target level 1LVt, the pass voltage Vpass is maintained at the second target level 2LVt, and the read voltage Vrd is maintained at the third target level 3LVt, a channel may be formed in cell strings. Memory cells may be read according to the read voltage Vrd.

At the fifth time T5, the selected word line Sel_WL and the unselected word lines Unsel_WL may be discharged. The pre-compensation voltage Vp that is lower than the compensation voltage Vcp may be applied to the first and second pass word lines 1PWL and 2PWL.

From the sixth to seventh times T6 to T7, the pre-compensation voltage Vp may be applied to the first and second pass word lines 1PWL and 2PWL and the first and second pass word lines 1PWL and 2PWL may be discharged at the seventh time T7.

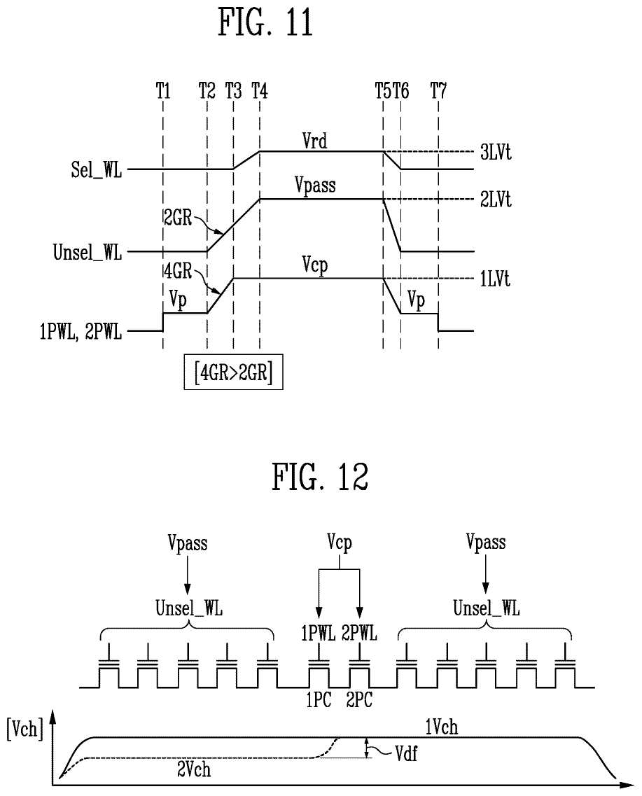

FIG. 12 is a diagram illustrating the effect of an embodiment of the present disclosure.

Referring to FIG. 12, during a read operation, when at least one of the first and second pass cells 1PC and 2PC located in the cell string is turned off, or turned on late, a channel may be divided into regions where a first channel voltage 1Vch and a second channel voltage 2Vch which are different from each other are applied, based on at least one of the first and second pass cells 1PC and 2PC.

The first channel voltage 1Vch may be applied to a region of the channel which is adjacent to the bit line and the second channel voltage 2Vch may be applied to a region of the channel which is adjacent to the source line. When a voltage difference Vdf occurs in the channel, hot electrons may occur in a region where the voltage difference Vdf occurs. When the hot electrons are injected into memory cells, the threshold voltage of the memory cells may change, thereby decreasing the reliability of the read operation.

As described above with reference to the first to third embodiments of the present disclosure, when the compensation voltage Vcp applied to the first and second pass word lines 1PWL and 2PWL, which are coupled to the first and second pass cells 1PC and 2PC, reaches the target level more rapidly than the pass voltage Vpass applied to the unselected word lines Unsel_WL, the channel voltage may be maintained at the first channel voltage 1Vch when the pass voltage Vpass reaches the target level, regardless of the region. Accordingly, in an embodiment, the occurrence of hot electrons in the cell string may be restrained and the channel of the cell strings may be formed uniformly, thereby improving the reliability of the read operation.

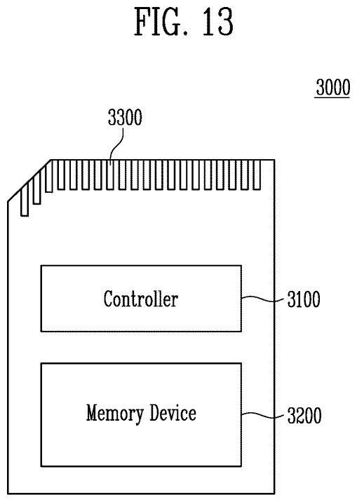

FIG. 13 is a diagram illustrating a memory card system 3000 to which a memory device according to an embodiment of the present disclosure is applied.

Referring to FIG. 13, the memory card system 3000 may include a controller 3100, a memory device 3200, and a connector 3300.

The controller 3100 may be coupled to the memory device 3200. The controller 3100 may be configured to access the memory device 3200. For example, the controller 3100 may control a program operation, a read operation or an erase operation, or a background operation of the memory device 3200. The controller 3100 may be configured to provide an interface between the memory device 3200 and a host. The controller 3100 may be configured to drive firmware for controlling the memory device 3200. For example, the controller 3100 may include components such as a Random Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may be configured to communicate with the external device through at least one of various communication protocols such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be defined by at least one of the above-described various communication protocols.

The memory device 3200 may include a plurality of memory cells and may be configured in the same manner as the memory device 100 shown in FIG. 1.

The controller 3100 and the memory device 3200 may be integrated into a single semiconductor device to constitute a memory card. For example, the controller 3100 and the memory device 3200 may constitute a memory card such as a personal computer (PC) (Personal card Computer Memory Card International Association (PCMCIA)), a Compact Flash (CF) card, a Smart Media Card (SM and SMC), a memory stick, a Multi-Media Card (MMC, RS-MMC, MMCmicro, or eMMC), an SD card (SD, miniSD, microSD, or SDHC), and a Universal Flash Storage (UFS).

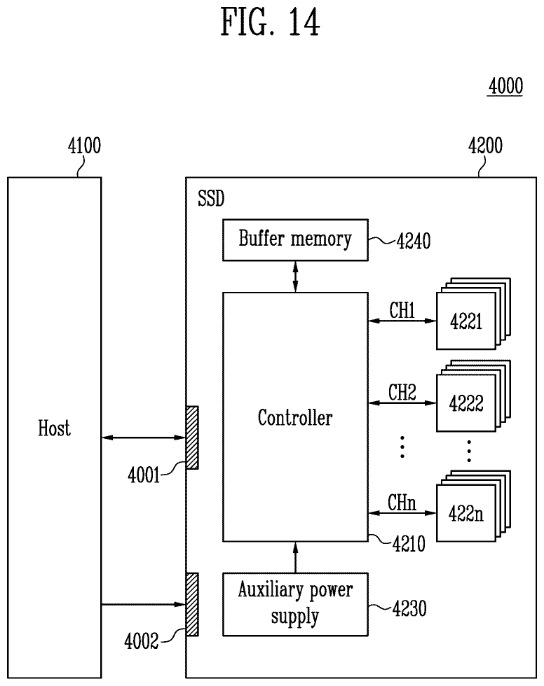

FIG. 14 is a diagram illustrating a solid state drive (SSD) system 4000 to which a memory device according to an embodiment of the present disclosure is applied.

Referring to FIG. 14, the SSD system 4000 may include a host 4100 and an SSD 4200. The SSD 4200 may exchange a signal with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. For example, the signals may be based on an interface between the host 4100 and the SSD 4200. For example, the signals may be defined by at least one of interfaces such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), an Integrated Drive Electronics (IDE), Firewire, Universal Flash Storage (UFS), WI-FI, Bluetooth, and NVMe interfaces.

The plurality of memory devices 4221 to 422n may include a plurality of memory cells configured to store data. Each of the plurality of memory devices 4221 to 422n may be configured in the same manner as the memory device 100 shown in FIG. 1.

The auxiliary power supply 4230 may be coupled to the host 4100 through a power connector 4002. The auxiliary power supply 4230 may receive power input from the host 4100 and charge the power. When the supply of power from the host 4100 is not normal, the auxiliary power supply 4230 may provide power of the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 may serve as a buffer memory of the SSD 4200. For example, the buffer memory 4240 may store data received from the host 4100 or data received from the plurality of memory devices 4221 to 422n, or may store metadata (e.g., mapping tables) of the memory devices 4221 to 422n. The buffer memory 4240 may include volatile memories such as DRAM, SDRAM, DDR SDRAM, and LPDDR SDRAM, or non-volatile memories such as FRAM, ReRAM, STT-MRAM, and PRAM.

According to various embodiments of the present disclosure, the reliability of a read operation of a memory device may be improved.

What is claimed is:

1. A memory device, comprising:
memory cells located between a bit line and a source line;
pass cells located between the memory cells;
word lines coupled to the memory cells;
pass word lines coupled to the pass cells; and
a voltage generator configured to apply a read voltage to a selected word line among the word lines, a pass voltage to unselected word lines among the word lines, and a compensation voltage to the pass word lines during a read operation,
wherein the voltage generator is configured to raise the compensation voltage more rapidly than the pass voltage.

2. The memory device of claim 1, wherein a target level of the compensation voltage is greater than or equal to a target level of the pass voltage.

3. The memory device of claim 1, wherein a rising slope of the compensation voltage is greater than a rising slope of the pass voltage.

4. The memory device of claim 1, wherein the voltage generator is configured to output the pass voltage and the compensation voltage simultaneously.

5. The memory device of claim 1, wherein the voltage generator is configured to further output a pre-compensation voltage less than the compensation voltage to the pass word lines before outputting the compensation voltage.

6. The memory device of claim 1, wherein the voltage generator is configured to further output a pre-compensation voltage less than the compensation voltage to the pass word lines after outputting the compensation voltage during a predetermined time.

7. The memory device of claim 1, wherein the voltage generator is configured to:
discharge the word lines after outputting the read voltage during a predetermined time,
apply a next read voltage to the selected word line, and
apply the pass voltage to the unselected word lines.

8. The memory device of claim 1, wherein the voltage generator is configured to maintain the compensation voltage applied to the pass word lines when the word lines are discharged.

9. A method of operating a memory device, the method comprising:
applying a compensation voltage to pass word lines located between word lines;
applying a pass voltage to unselected word lines among the word lines; and
applying a read voltage to a selected word line among the word lines when the compensation voltage rises to a first target level and the pass voltage rises to a second target level,
wherein the compensation voltage rises to the first target level before the pass voltage rises to the second target level.

10. The method of claim 9, wherein a rising slope of the compensation voltage is greater than a rising slope of the pass voltage.

11. The method of claim 9, wherein the second target level is set to be equal to the first target level.

12. The method of claim 9, wherein the second target level is set to be less than the first target level.

13. The method of claim 9, further comprising, before the applying of the compensation voltage, applying a pre-compensation voltage less than the compensation voltage to the pass word lines.

14. The method of claim 13, wherein the pre-compensation voltage is set to be greater than 0 volts.

15. The method of claim 9, further comprising, after the applying of the compensation voltage, applying a pre-compensation voltage less than the compensation voltage to the pass word lines.

16. The method of claim 9, further comprising, after the read voltage is applied to the selected word line during a predetermined time:
discharging the word lines;
applying the pass voltage to the unselected word lines; and
applying a next read voltage to the selected word line.

17. The method of claim 16, wherein in the discharging of the word lines, the compensation voltage applied to the pass word lines is maintained.

18. A method of operating a memory device, the method comprising:
turning on, between memory cells included in a memory block and pass cells located between the memory cells, the pass cells;
turning on unselected memory cells among the memory cells after the pass cells are turned on; and
reading selected memory cells among the memory cells.

19. The method of claim 18, wherein in the turning on of the pass cells, a compensation voltage higher than 0 volts is applied to pass word lines coupled to gates of the pass cells.

20. The method of claim 18, wherein in the turning on of the pass cells, a pass voltage which rises is applied to unselected word lines coupled to gates of the unselected memory cells.
